(19) United States
(12) Patent Application Publication
(10) Pub. No.: US 2003/0045099 A1
(43) Pub. Date: Mar. 6, 2003

(54) Method of forming a self-aligned contact hole

(75) Inventors: Yu-Chi Sun, Pingjen City (TW); Tse-Yao Huang, Taipei (TW)

Correspondence Address: Richard P. Brg, Esq., c/o LADAS & PARRY, Suite 2100, 5670 Wilshire Boulevard, Los Angeles, CA, 90036-5679, US

(73) Assignee: NANYA TECHNOLOGY CORPORATION

(21) Appl. No.: 10/016,896

(22) Filed: Dec. 13, 2001

(30) Foreign Application Priority Data
Sep. 4, 2001 (TW) 90121877

(51) Int. Cl. H01L 21/302; H01L 21/311

(52) U.S. Cl. 438/689; 438/700; 438/709; 438/723

(57) ABSTRACT

A method of forming a self-aligned contact hole suitable for a semiconductor substrate having a pair of gate electrodes. First, a nitride etching stop layer is formed over the gate electrodes and the semiconductor substrate. Then, an oxide insulating layer is formed on the nitride etching stop layer, Next, the oxide insulating layer is plasma-etched by an etching gas containing C₅F₈ and CHF₃ or C₄F₆ and CHF₃ so as to form a self-aligned contact hole between the pair of gate electrode.

### BACKGROUND OF THE INVENTION

1. Field of the Invention

The present invention relates to the manufacture of semiconductor devices, more particularly, to a method for increasing the etching selectivity of oxide insulating layer/silicon nitride during the formation of a self-aligned contact hole.

2. Description of the Related Art

FIGS. 1A to 1C and 1C′ are cross-sections showing the manufacturing steps of a self-aligned contact hole during the fabrication of dynamic random access memory (DRAM), in accordance with the prior art.

FIG. 1A shows a semiconductor substrate 10 having a thermal gate oxide 14/gate electrode 16 on the semiconductor substrate 10. An ion-implanting region 12, serving as a source/drain region, is formed on the surface of the semiconductor substrate 10. A spacer 18 is formed by a conventional method on the sidewalls of gate electrodes 14. An etching stop layer 20 is formed above the semiconductor substrate 10. It includes a bottom part B adjacent to the ion-implanting region 12 and a corner part C as shown in FIG. 1A.

Next, referring to FIG. 1B, an insulating layer 22 of silicon oxide is deposited over the semiconductor substrate 10. In addition, a photoresist pattern 24 having an opening 26 aligning the ion-implanting region 12 is defined on the insulating layer 22.

Afterward, referring to FIGS. 1C and 1C′, the insulating layer 22 is etched by an etching gas containing (A) C₅F₈, O₂, and argon or gas (B) C₄F₈, CH₂F₂, and argon gas in a plasma chamber thus forming a self-aligned contact (SAC) hole 28 or 28′ exposing the ion-implanting region 12.

The design rule of the semiconductor devices continues to shrink about 0.14 μm. The etching of a contact hole is generally a critical process.

The etching process gas composition of (A) described above, however, provides insufficient etching selectivity relative to the corner part C of the underlying etching stop layer 20. As a result, the etching stop layer 20 near the corner part C is easily over-etched as shown in FIG. 1C. This can cause undesirable short between the gate 16 and a conductive line filled into the contact hole 28 (not shown). On the other hand, the gas composition of (B) described above provides lower etching selectivity relative to the bottom part B of the underlying etching stop layer 20 so that the surface of semiconductor substrate 10 is over-etched. This can result in poor performance in the metal-oxide-semiconductor transistor.

### SUMMARY OF THE INVENTION

In view of the above disadvantages, an object of the invention is to provide a method of forming a self-aligned contact hole. This method is capable of equalizing the etching rate at the corner and the bottom of the etching stop layer.

Accordingly, the above object is attained by providing a method of forming a self-aligned contact hole suitable for a semiconductor substrate having a pair of gate electrodes. First, a nitride etching stop layer is formed over the gate electrode and semiconductor substrate. Then, an oxide insulating layer is formed on the nitride etching stop layer, Next, the oxide insulating layer is plasma-etched by an etching gas containing C₅F₈ and CHF₃ or C₄F₆ and CHF₃ so as to form a self-aligned contact hole between the pair of gate electrodes.

In an embodiment of the invention, the oxide insulating layer is preferably borophosphosilicate glass (BPSG) or silicon oxide deposited using tetra-ethyl-ortho-silicate (TEOS)as reactive gas. Also, the nitride etching stop layer is preferably silicon nitride or silicon oxy-nitride.

Moreover, in another embodiment of the invention, the etching gas further comprises an inert gas such as argon gas.

Furthermore, in the method of forming a self-aligned contact hole, the C₅F₈/CHF₃ mixture ratio of the etching gas is preferably between 0.4 and 0.75

According to the method of the invention, an etching gas containing C₅F₈ and CHF₃ or C₄F₆ and CHF₃ is used when the insulating layer is etched to form a self-aligned contact hole. In this step, the etching rate at the corner and the bottom of the etching stop layer can be equalized.

### BRIEF DESCRIPTION OF THE DRAWINGS

The preferred embodiment of the invention is hereinafter described with reference to the accompanying drawings in which:

FIGS. 1A to 1C and 1C′ are cross-sections showing the manufacturing steps of a self-aligned contact hole during the fabrication of dynamic random access memory (DRAM), in accordance with the prior art.

FIGS. 2A to 2C are cross-sections showing the manufacturing steps of a self-aligned contact hole during the fabrication of dynamic random access memory (DRAM), in accordance with the preferred embodiment of the invention.

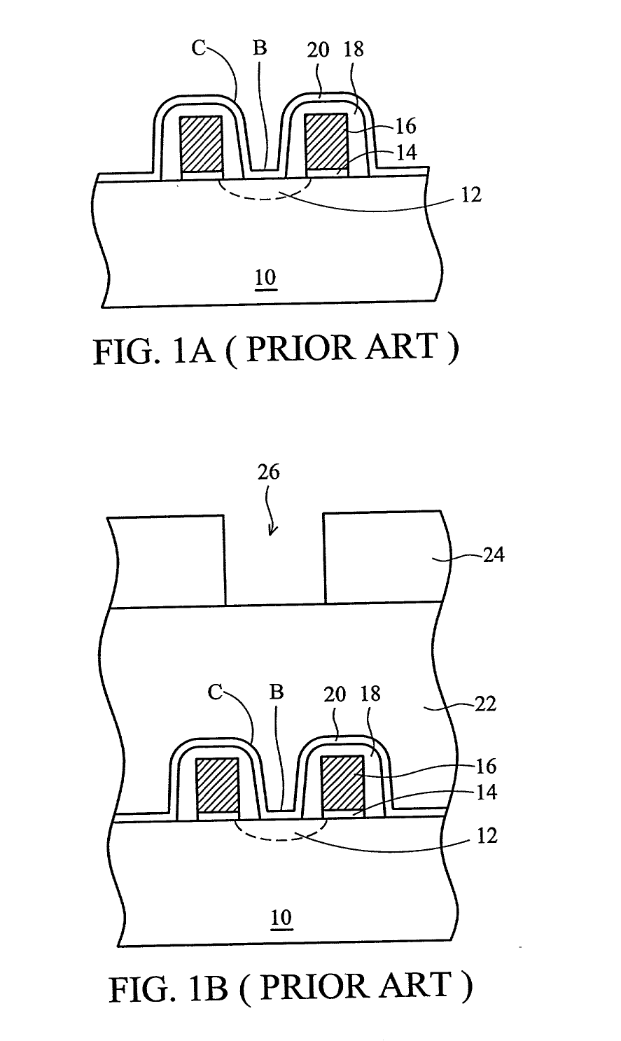

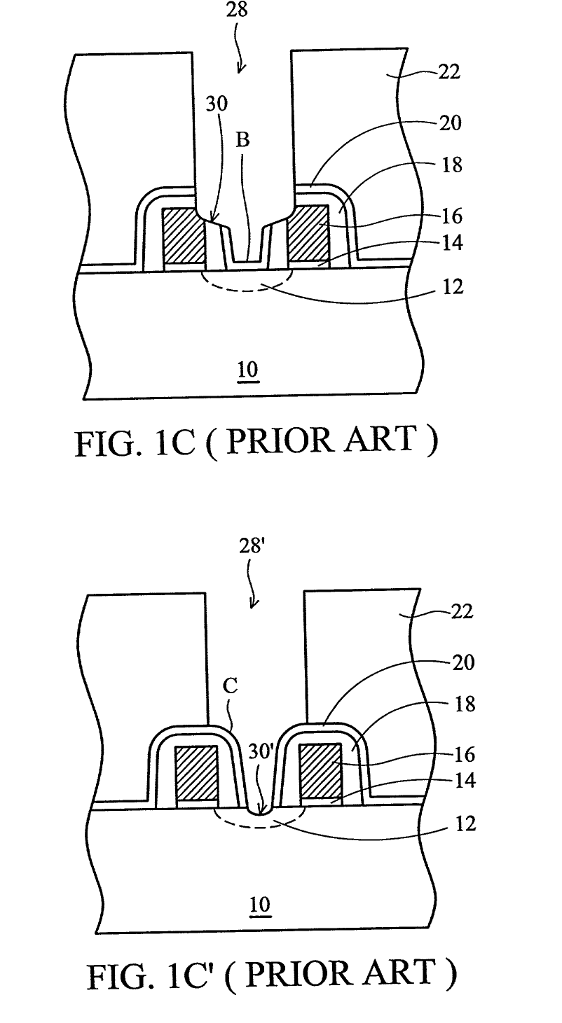

### DETAILED DESCRIPTION OF THE PREFERRED EMBODIMENTS

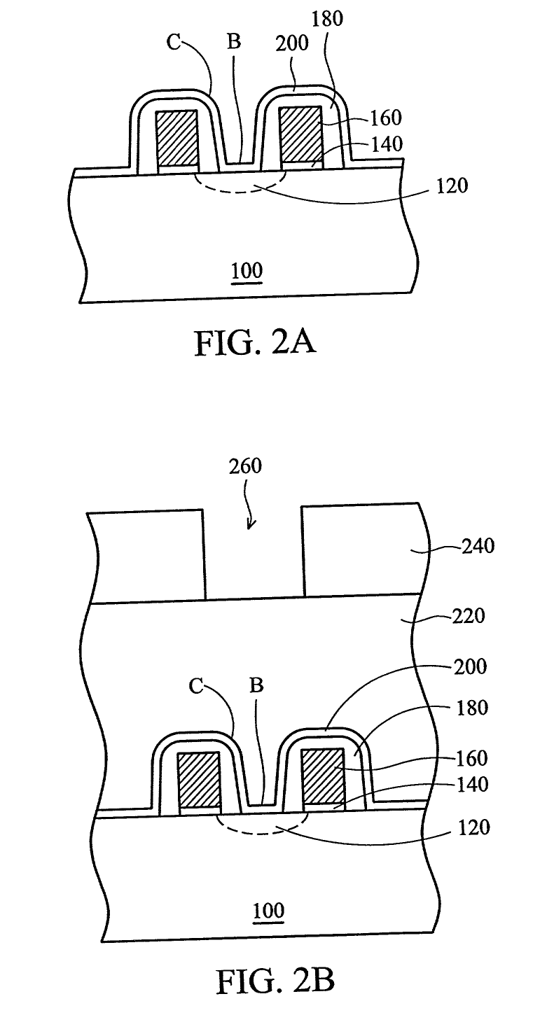

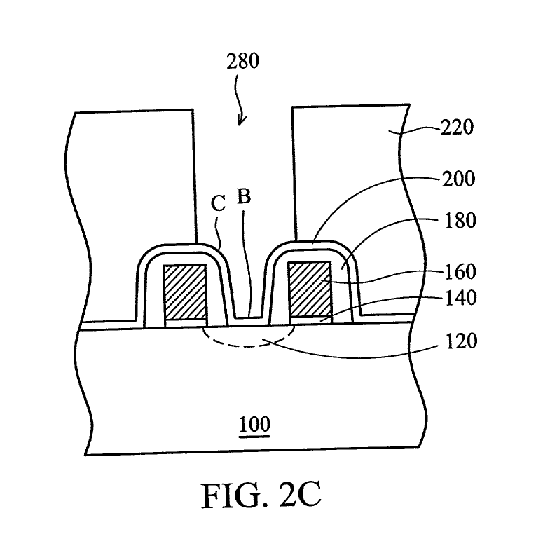

FIG. 2A to FIG. 2C are cross-sections showing the manufacturing steps of a self-aligned contact hole during the fabrication of dynamic random access memory (DRAM), according to the invention.

FIG. 2A shows a semiconductor substrate 100, consisting of P-type mono-crystal silicon. A thermal gate oxide 140/gate electrode 160 is formed on the semiconductor substrate 100. Ion-implanting region 120 serves as source/drain region, formed on the surface of the semiconductor substrate 100. A spacer 180 of silicon nitride is formed by conventional method on the sidewalls of gate electrodes 140.

An etching stop layer 200, having a thickness ranging 100 to 200 angstroms, is formed above the exposed semiconductor substrate 100 and the spacer 180 (or gate electrode 140) by low-pressure chemical vapor deposition (LPCVD). The etching stop layer 200 is of a nitride-containing material, such as silicon nitride or silicon oxy-nitride. Since the etching stop layer 200 is deposited according to the profile of the gate electrode 140, it includes a bottom part B adjacent to the ion-implanting region 120 and a corner part C as shown in FIG. 2A.

Next, referring to FIG. 2B, an insulating layer 220 of silicon oxide, having a thickness between about 6,000 and 10,000 angstroms, is deposited over the semiconductor substrate 100 by chemical vapor deposition (CVD) using silane and tetra-ethyl-ortho-silicate (TEOS) as the reactive gas. Borophosphosilicate glass (BPSG), deposited by a reactive gas containing tri-methyl-phosphate (TEPO) and tri-ethyl-borate (TEB) can be used to replace the silicon oxide material mentioned above. In addition, a conventional photolithography process comprising photoresist coating, photoresist exposing, and developing forms a photoresist pattern 240 having an opening 260 aligning the ion-implanting region 120.

Afterward, referring to FIG. 2C, the oxide insulating layer 220 is etched by an etching gas containing C₅F₈, CHF₃, and argon gas in a plasma chamber, thus forming a self-aligned contact (SAC) hole 280. In this step, the pressure of the plasma chamber is kept at 30 to 70 mtorr. Also, the C₅F₈/CHF₃ mixture ratio is controlled between 0.4 and 0.75. The exposed etching stop layer 200 in the contact hole 280 is then removed by etching to expose the ion-implanting region 120.

While the invention has been described with reference to various illustrative embodiments, the description is not intended to be construed in a limiting sense. Various modifications of the illustrative embodiments, as well as other embodiments of the invention, will be apparent to those person skilled in the art upon reference to this description. It is therefore contemplated that the appended claims will cover any such modifications or embodiments as may fall within the scope of the invention defined by the following claims and their equivalents.

What is claimed is:

1. A method of forming a self-aligned contact hole suitable for a semiconductor substrate having a pair of gate electrodes, comprising the steps of:
forming a nitride etching stop layer over the gate electrode and the semiconductor substrate;
forming an oxide insulating layer on the nitride etching stop layer; and
plasma-etching the oxide insulating layer by an etching gas containing C₅F₈ and CHF₃ so as to form a self-aligned contact hole between the pair of gate electrode.

2. A method of forming a self-aligned contact hole as claimed in claim 1, wherein the oxide insulating layer is BPSG.

3. A method of forming a self-aligned contact hole as claimed in claim 1, wherein the oxide insulating layer is silicon oxide formed by a reactive gas containing TEOS.

4. A method of forming a self-aligned contact hole as claimed in claim 1, wherein the nitride etching stop layer is silicon nitride.

5. A method of forming a self-aligned contact hole as claimed in claim 1, wherein the nitride etching stop layer is silicon oxy-nitride.

6. A method of forming a self-aligned contact hole as claimed in claim 1, wherein the etching gas further comprises an inert gas.

7. A method of forming a self-aligned contact hole as claimed in claim 6, wherein the inert gas is argon gas.

8. A method of forming a self-aligned contact hole as claimed in claim 1, wherein the C₅F₈/CHF₃ mixture ratio of the etching gas is between 0.4 and 0.75.

9. A method of forming a self-aligned contact hole suitable for a semiconductor substrate having a pair of gate electrodes, comprising the steps of:
forming a nitride etching stop layer over the gate electrodes and the semiconductor substrate;
forming a oxide insulating layer on the nitride etching stop layer; and
plasma-etching the oxide insulating layer by an etching gas containing C₄F₆ and CHF₃ so as to form a self-aligned contact hole between the pair of gate electrode..

10. A method of forming a self-aligned contact hole as claimed in claim 9, wherein the oxide insulating layer is BPSG.

11. A method of forming a self-aligned contact hole as claimed in claim 9, wherein the oxide insulating layer is silicon oxide formed by a reactive gas containing TEOS.

12. A method of forming a self-aligned contact hole as claimed in claim 9, wherein the nitride etching stop layer is silicon nitride.

13. A method of forming a self-aligned contact hole as claimed in claim 9, wherein the nitride etching stop layer is silicon oxy-nitride.

14. A method of forming a self-aligned contact hole as claimed in claim 9, wherein the etching gas further comprises an inert gas.

15. A method of forming a self-aligned contact hole as claimed in claim 13, wherein the inert gas is argon gas.
